(19) United States
(12) Patent Application Publication
(10) Pub. No.: US 2026/0090362 A1
(43) Pub. Date: Mar. 26, 2026

(54) SEPARATE METAL REGIONS IN A LAYER OF A PILLAR BAR VIA ON A TRANSISTOR ROW IN AN INTEGRATED CIRCUIT (IC) TO REDUCE STRESS AND RELATED FABRICATION METHODS

(71) Applicant: QUALCOMM Incorporated, San Diego, CA (US)

(72) Inventors: Wenyue Lydia Zhang, San Diego, CA (US); Alireza Vali, San Diego, CA (US); Jiaping Zhang, San Diego, CA (US); Yonghao An, San Diego, CA (US)

(21) Appl. No.: 18/891,780

(22) Filed: Sep. 20, 2024

(51) Int. Cl. H01L 23/528; H01L 23/373; H01L 23/522; H01L 23/532; H01L 27/082

(52) U.S. Cl. CPC H10W 20/435; H10D 84/645; H10W 20/42; H10W 20/427; H10W 20/4421; H10W 20/48; H10W 40/258

(57) ABSTRACT

An integrated circuit (IC) may include a pillar bar disposed in a bar area over a row of transistors to conduct a current through the transistors and to conduct heat away from the transistors. The pillar bar includes a top metal layer, a bottom metal layer coupled to a terminal of each of the transistors in the row, and at least one intermediate layer between the top metal layer and the bottom metal layer. When heated by the transistors, the metal in the pillar bar expands at a different rate than the IC substrate, causing heat-related stress that may damage the IC. In a pillar bar disclosed herein, one of the intermediate layers includes separate metal regions separated by a non-metal material in the bar area. The pillar bar includes a central metal region and separate metal regions between the central metal region and the ends of the pillar bar.

### TECHNICAL FIELD

The technology of the disclosure relates generally to transistors providing power in integrated circuits (ICs) and, more particularly, to reducing the increases in stress associated with reducing the area of a pillar bar in a power circuit.

### BACKGROUND

An integrated circuit (IC) die may include power circuits, such as a power amplifier circuit, to provide power to circuits on the IC die or on other dies in a package or module. Since the current requirements in such situations may be many times the current capacity of a single transistor, a power amplifier on an IC die may include several transistors operated in parallel. For purposes of area optimization, the transistors of a power amplifier may be physically arranged in parallel in a row or one-dimensional array on an IC die. Although some transistors, such as heterojunction bipolar transistors (HBTs) for example, are designed for higher current capacity than transistors typically employed in logic circuits, the transmission of a high current through multiple transistors densely arranged in a row generates a large amount of heat. One effect of such heat is to increase the temperature of the IC die in the area of the row of transistors, which can cause damage to the transistors above a threshold temperature. In this regard, a pillar bar is provided in the metal layers above the row of transistors to conduct heat upward away from the transistors and dissipate the heat to a larger heat sink or to the environment. Another effect of the heat is the creation of stresses parallel to a substrate of the IC die in the proximity of the transistor row due to heat-related expansion of the pillar bar. These stresses can be significant enough to cause cracking in the substrate.

### SUMMARY

Aspects disclosed in the detailed description include separate metal regions in a layer of a pillar bar via on a transistor row in an integrated circuit (IC) to reduce stress. Related methods of making an IC, including separate metal regions in a layer of a pillar bar, are also disclosed. An IC may include a pillar bar disposed in a bar area over a row of transistors to conduct a current through the transistors and to conduct heat away from the transistors. The pillar bar includes a bottom metal layer coupled to a terminal of each of the transistors in the row. The pillar bar also includes a top metal layer and at least one intermediate layer between the bottom metal layer and the top metal layer. When the pillar bar is heated by the row of transistors, the metal layers in the pillar bar expand at a different rate than a substrate on which the row of transistors is formed, and this difference can cause heat-related stress that may damage an IC. In an exemplary pillar bar disclosed herein, one of the intermediate layers in the pillar bar includes separate metal regions in the bar area. In some examples, the separate metal regions may be separated by a non-metal material. Since the heat-related stress is greatest towards the ends of the pillar bar, while the hottest area of the pillar bar may be in a central area midway between the first and second ends (e.g., of the row), the separate metal regions in the intermediate layer may, in some examples, include a central metal region in the central area and separate metal regions between the central area and each end of the pillar bar. Having separate metal regions in the intermediate metal layer can reduce heat-related stresses and improve reliability in the IC.

In this regard, in one aspect, an IC is disclosed. The IC includes a substrate, a row of transistors on the substrate, the row of transistors extending in a first direction, and a pillar bar comprising layers in a bar area extending on the row of transistors. The layers include a top metal layer, a bottom metal layer coupled to a terminal of each transistor in the row of transistors, and at least one intermediate layer between the top metal layer and the bottom metal layer, wherein a first intermediate layer of the at least one intermediate layer comprises separate metal regions in the bar area.

In this regard in one aspect, a method of fabricating an IC is disclosed. The method includes forming a substrate, forming transistors on the substrate in a row extending in a first direction, and forming a pillar bar comprising layers in a bar area extending over the row of transistors in a direction orthogonal to the substrate. The layers include a top metal layer, a bottom metal layer coupled to a terminal of each transistor in the row of transistors, and at least one intermediate layer between the top metal layer and the bottom metal layer, wherein a first intermediate layer of the at least one intermediate layer comprises separate metal regions in the bar area.

In this regard, in one aspect, an IC package comprising a first IC comprising logic circuits and a second IC comprising a power amplifier disposed on a substrate and configured to supply power to the first IC is disclosed. The power amplifier includes a row of transistors disposed on the substrate and extending in a first direction, and a pillar bar comprising a stack of layers in a bar area extending over the row of transistors in a direction orthogonal to the substrate. The stack of layers includes a top metal layer, a bottom metal layer coupled to a terminal of each transistor in the row of transistors, and at least one intermediate layer between the top metal layer and the bottom metal layer, wherein a first intermediate layer of the at least one intermediate layer comprises separate metal regions in the bar area. The bar area includes a central area midway between a first end and a second end in the first direction.

### BRIEF DESCRIPTION OF THE DRAWINGS

FIG. 1 is an illustration of a top-down view of an integrated circuit (IC), including a row of transistors coupled in parallel to provide greater current capacity, such as in a power amplifier;

FIG. 2 is an illustration of the row of transistors in FIG. 1, including a pillar bar in a bar area covering the row of transistors and including continuous metal layers to conduct heat away from the transistors but also generating high stresses at each end of the bar area;

FIG. 3 is a top-down view of a portion of a row of transistors on an IC, as shown in FIG. 1;

FIG. 4 is a cross-sectional side view of a portion of a row of transistors, as shown in FIG. 3, with the metal layers of a conventional pillar bar providing an electrical connection and conducting heat away from the transistors;

FIG. 5 is an illustration of the IC in FIG. 1, including an exemplary pillar bar in which a first example of an intermediate layer includes separate metal regions between a central area and the ends of the bar area to reduce heat-related stresses;

FIG. 6 is a cross-sectional side view of an example of the layers in a pillar bar as disclosed herein, in which an intermediate layer includes separate metal regions to reduce heat-related stress as in the pillar bar in FIG. 5;

FIG. 7 is a graphical representation comparing stresses created by the pillar bar in FIG. 2 and stresses created by the pillar bar in FIG. 3, showing a reduction in stresses towards the ends of the bar area;

FIG. 8 is a flowchart of an exemplary method of manufacturing an IC, such as the IC in FIG. 5;

FIGS. 9-12 are additional examples of intermediate layers, including separate metal regions, which may be employed in pillar bars to reduce heat-related stresses at each end of a bar area in an IC;

FIGS. 13-14 are cross-sectional side views of additional examples of the pillar bar as disclosed herein, in which different intermediate layers include separate metal regions to reduce heat-related stress, as shown in FIGS. 5 and 9-12;

FIG. 15 is a block diagram of an exemplary processor-based system that can include ICs with a pillar bar to conduct heat away from a row of transistors, where the pillar bar includes at least one intermediate layer with separate metal regions to reduce heat-induced stresses; and

FIG. 16 is a block diagram of an exemplary wireless communication device that includes radio-frequency (RF) components that can include ICs with a pillar bar to conduct heat away from a row of transistors, where the pillar bar includes at least one intermediate layer with separate metal regions to reduce heat-induced stresses.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include separate metal regions in a layer of a pillar bar on a transistor row in an integrated circuit (IC) to reduce stress. Related methods of making an IC, including separate metal regions in a layer of a pillar bar, are also disclosed. An IC may include a pillar bar disposed in a bar area over a row of transistors to conduct a current through the transistors and to conduct heat away from the transistors. The pillar bar includes a bottom metal layer coupled to a terminal of each of the transistors in the row. The pillar bar also includes a top metal layer and at least one intermediate layer between the bottom metal layer and the top metal layer. When the pillar bar is heated by the row of transistors, the metal layers in the pillar bar expand at a different rate than a substrate on which the row of transistors is formed, and this difference can cause heat-related stress that may damage an IC. In an exemplary pillar bar disclosed herein, one of the intermediate layers in the pillar bar includes separate metal regions in the bar area. In some examples, the separate metal regions may be separated by a non-metal material. Since the heat-related stress is greatest towards the ends of the pillar bar, while the hottest area of the pillar bar may be in a central area midway between the first and second ends (e.g., of the row), the separate metal regions in the intermediate layer may, in some examples, include a central metal region in the central area and separate metal regions between the central area and each end of the pillar bar. Having separate metal regions in the intermediate metal layer can reduce heat-related stresses and improve reliability in the IC.

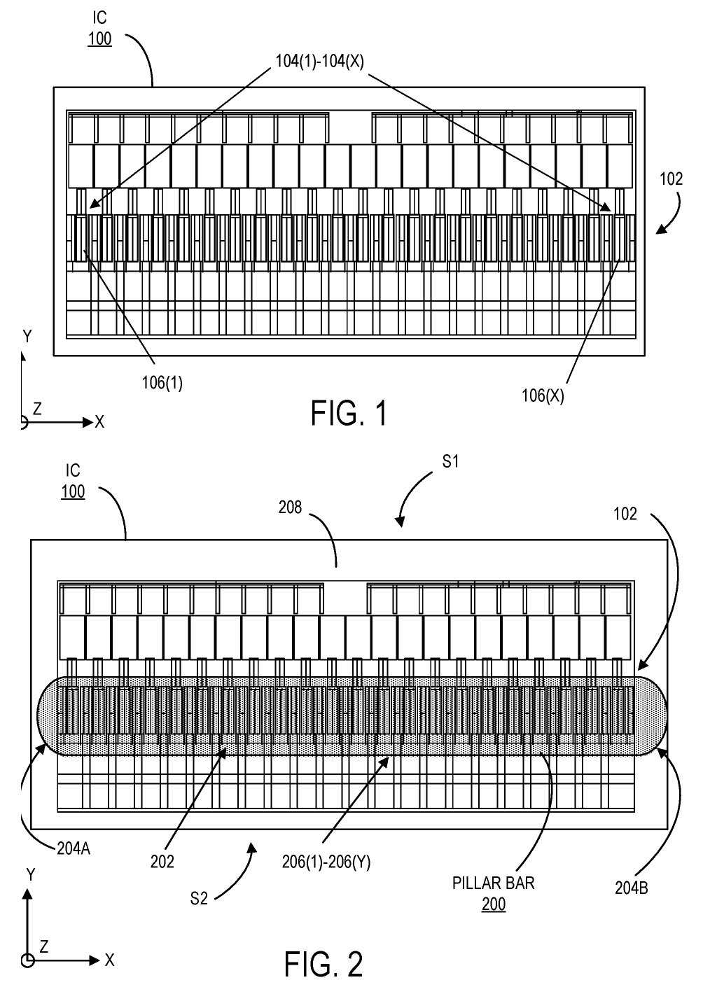

FIG. 1 is an illustration of a top-down view of an integrated circuit (IC) 100, including a row 102 of transistors 104(1)-104(X). To provide power to other circuits (not shown) on the IC 100 or circuits on another IC in an IC package including the IC 100, the transistors 104(1)-104(X) may be coupled in parallel, such as in a power amplifier, for example. The transistors 104(1)-104(X) are each capable of conducting a large current through terminals 106(1)-106(X). The transistors 104(1)-104(X) may be densely arranged in the row 102 to minimize the area of the IC 100. With several transistors 104(1)-104(X) conducting large currents, a large amount of heat may be generated in a small area A₁₀₂ including the row 102, which can quickly increase a temperature of the transistors 102(1)-102(X) if the heat is not dissipated at a sufficient rate. Above a threshold temperature, the transistors 104(1)-104(X) can be permanently damaged, so a mechanism for providing heat dissipation is needed.

FIG. 2 is an illustration of the row 102 of transistors 104(1)-104(X) on the IC 100 in FIG. 1, which is referenced below, and includes a pillar bar 200 in a bar area 202 over the row 102 of transistors 104(1)-104(X). Thus, the bar area 202 extends farther in a first, X-axis direction from a first end 204A to a second end 204B than in a second, Y-axis direction from a first side S1 to a second side S2 to cover the row 102 of transistors 104(1)-104(X).

The pillar bar 200 includes metal layers 206(1)-206(Y) (where Y=5 in this example) in the bar area 202 to conduct heat away from the transistors 104(1)-104(X) and also to conduct a current that flows through each of the terminals 106(1)-106(X). The heat generated in the transistors 104(1)-104(X) is conducted upward through the metal layers 206(1)-206(Y) away from the transistors 104(1)-104(X), which increases the temperature of the pillar bar 200. Since the pillar bar 200 is longer in the first, X-axis direction than in the second, Y-axis direction, the pillar bar 200 may expand farther in the first direction than the second direction when heated by the transistors 104(1)-104(X). Because the metal layers 206(1)-206(Y) are formed of a different material than a substrate 208 of the IC 100, which may be an appropriate semiconductor material (e.g., gallium arsenide (GaAs)), the rates of expansion of the pillar bar 200 and the substrate 208 of the IC 100 may differ. As a result of the above factors, when the pillar bar 200 is heated, it can induce high stresses on the substrate 208 in the first direction, and these stresses have been found to cause damage (e.g., cracking) in the substrate 208, reducing the reliability of the ICs 100 manufactured with the pillar bar 200 as shown in FIG. 2.

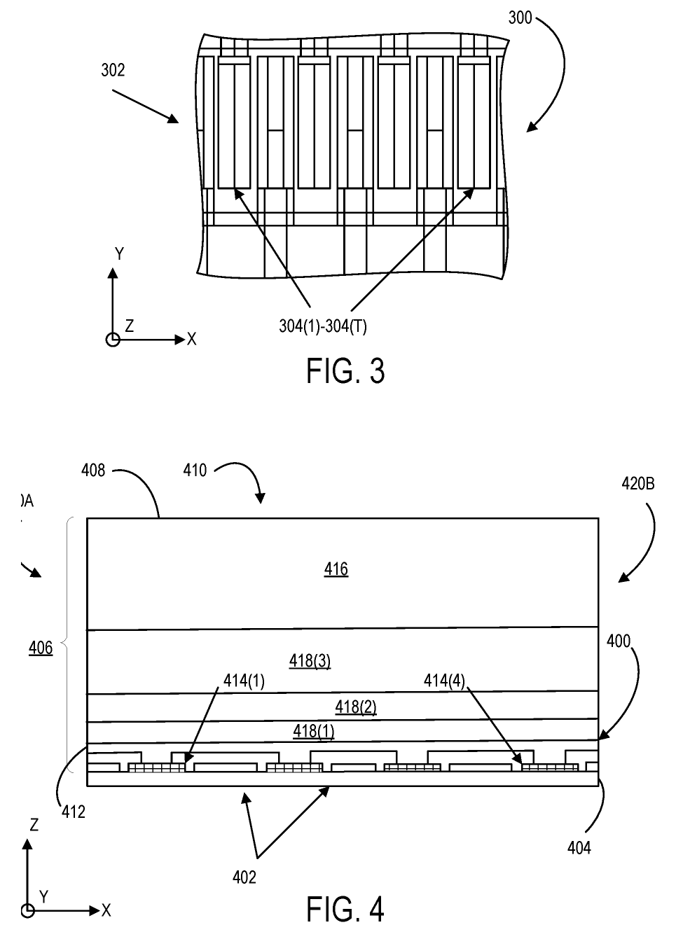

FIG. 3 is a top-down view of a partial row 300 of transistors 302, including terminals 304(1)-304(T), where T=4 in this example. The partial row 300 of transistors 302 may be a portion of the row 102 of transistors 104(1)-104(X) shown in FIGS. 1 and 2. FIG. 3 is provided to show a detailed view of the transistors formed on the substrate in FIG. 4.

FIG. 4 is a cross-sectional side view of a partial row 400 of transistors 402, which may be the partial row 300 of transistors 302 in FIG. 3. The partial row 400 of transistors 402 is disposed on a substrate 404 and further includes layers 406 of a pillar bar 408 that conducts current through the transistors 402 and conducts heat away from the transistors 402. The pillar bar 408 is disposed in a bar area 410 over the partial row 400 of transistors 402, in a third, Z-axis direction.

The layers 406 in the pillar bar 408 include a bottom metal layer 412 disposed on terminals 414(1)-414(4), which may be the terminals 304(1)-304(4) shown in FIG. 3. The bottom metal layer 412 may be in direct or indirect contact with the terminals 304(1)-304(4) to provide both an electrical connection to the transistors 402 and a thermal connection through which heat may be conducted away from the transistors 402 and the substrate 404. In this context, the term “indirect contact” indicates that there is an intervening layer, and the term “direct contact” indicates that there is no intervening layer. The terminals 414(1)-414(4) may be electrically coupled to each other by the bottom metal layer 412.

The layers 406 also includes a top metal layer 416, which may be the thickest of the layers 406 in the third, Z-axis direction as the thicknesses of metal layers on an IC may increase farther from the substrate 404. The top metal layer 416 may extend over the entire bar area 410, having an oblong shape to cover the partial row 400 of transistors 402 in the third direction. The top metal layer 416 is a continuous metal layer over the bar area 410.

The layers 406 also includes at least one intermediate layer 418(1)-418(M), where M=3 in this example but may be any appropriate positive integer number. In the pillar bar 408, each of the intermediate layers 418(1)-418(3) are also continuous metal layers over the entire bar area 410. Thus, in addition to having a continuous top metal layer 416, the pillar bar 408 includes continuous metal layers 418(1)-418(3) in the third, Z-axis direction from the bottom metal layer 412 to the top metal layer 416 and continuous metal in the first, X-axis direction from a first end 420A to a second end 420B of the pillar bar 408. Although not limited in this regard, the layers 406, including the bottom metal layer 412, the top metal layer 416, and the intermediate metal layers 418(1)-418(3), may be formed of copper to provide electrical and thermal conductivity. As noted above, in response to being heated by the transistors 402, the pillar bar 408 may expand significantly in the first direction having a different (e.g., greater) coefficient of expansion than the semiconductor material of the substrate 404, resulting in significant stresses in the first direction that can cause damage to the substrate 404.

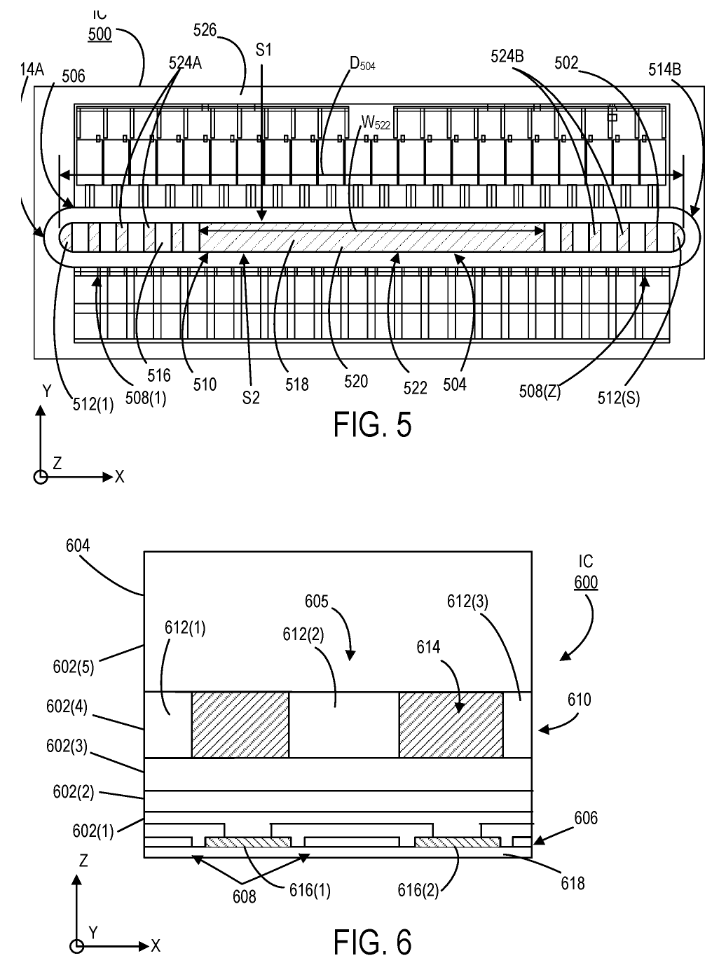

FIG. 5 is an illustration of an IC 500, including an exemplary pillar bar 502 disposed in a bar area 504 on a row 506 of transistors 508(1)-508(Z) on a substrate 526. The row 506 of transistors 508(1)-508(Z), which may be the row 102 in FIG. 1, extends in the first, X-axis direction in FIG. 5. FIG. 5 is a top-down cross-sectional view similar to the view in FIG. 2 but shows a cross-section of one example of a first intermediate layer 510 of the pillar bar 502 that includes separate metal regions 512(1)-512(S) in the bar area 504 to reduce heat-related stresses that may be induced in the IC 500 in response to heating of the transistors 508(1)-508(Z). The pillar bar 502 includes layers similar to the layers 406 shown in FIG. 4, but only the intermediate layer 510 is visible from the perspective in FIG. 5. See FIG. 6 for more detail.

The bar area 504 has an oblong shape that extends in the first direction and in a second, Y-axis direction to cover the row 506 of transistor 508(1)-508(Z). In other words, the row 506 of transistor 508(1)-508(Z) is between (e.g., directly between) the pillar bar 502 and the substrate 526 in a third, Z-axis direction. Based on the shape of the pillar bar 502, the greatest potential for expansion due to heating in the pillar bar 502 is in the first, X-axis direction between a first end 514A and a second end 514B of the bar area 504, so the greatest heat-related stresses are generated near the first and second ends 514A, 514B. In the pillar bar 502, however, rather than having a continuous metal layer at every intermediate layer, the pillar bar 502 includes the intermediate layer 510 with separate metal regions 512(1)-512(S) to reduce the heat-related stress in the first direction. The separate metal regions 512(1)-512(S) may be separated (from each other) by a non-metal material 516 that is disposed around each of the separate metal regions 512(1)-512(S) and, therefore, between any adjacent separate metal regions 512(1)-512(S). The non-metal material 516 may be a polymer, for example, which is less rigid and more elastic than the separate metal regions 512(1)-512(S), which may be formed of a metal 518 (e.g., copper).

Even though the separate metal regions 512(1)-512(S) expand when heated, stresses caused by the intermediate layer 510 in the first direction, towards the respective ends 514A and 514B, are reduced compared to a pillar bar 502, having only continuous metal layers because the intermediate layer 510 has less metal between the first end 514A and the second end 514B. In addition, some of the expansion of the separate metal regions 512(1)-512(S) may be absorbed by the deformation of the non-metal material 516.

As discussed above, the heat-related stress in the pillar bar 502 is greatest towards the first and second ends 514A, 514B of the bar area 504. However, the temperature of the pillar bar 502 may be the highest in a central area 520 midway between the first end 514A and the second end 514B in the first direction. For this reason, in the example of the intermediate layer 510 in FIG. 5, the intermediate layer 510 includes a central metal region 522 in the central area 520. To provide thermal conduction through the central area 520 in the third, Z-axis direction, the central metal region 522 may have a width W₅₂₂ in the first direction that is equal to or greater than half of a distance D₅₀₄ from the first end 514A to the second end 514B of the bar area 504 (e.g., W₅₂₂ >= D₅₀₄/2). The intermediate layer 510 also includes a plurality of first metal regions 524A between the central metal region 522 (e.g., the central area 520) and the first end 514A and a plurality of second metal regions 524B between the central metal region 522 and the second end 514B of the bar area 504. The central metal region 522, the plurality of first metal regions 524A, and the plurality of second metal regions 524B are among the separate metal regions 512(1)-512(S).

Although the separate metal regions 512(1)-512(S) are not limited in this regard, each of the plurality of first metal regions 524A and the plurality of second metal regions 524B extend across the bar area 504 in the second, Y-axis direction from a first side S1 to a second side S2 of the bar area 504. In addition, each of the separate metal regions 512(1)-512(S) contacts a continuous metal layer (not shown) immediately above, in the third direction, and another continuous metal layer (not shown) immediately below the separate metal regions 512(1)-512(S) to provide a conductive path for heat and electricity in the third direction.

The non-metal material 516 in this example extends in the second direction across the bar area 504 between adjacent first metal regions 524A from the first side S1 to the second side S2 and between adjacent second metal regions 524B from the first side S1 to the second side S2.

FIG. 6 is a cross-sectional side view of an IC 600 including layers 602(1)-602(T), where T=5, of a pillar bar 604 disposed in a bar area 605 on a row 606 of transistors 608 to show a first example of an intermediate layer 610 including separate metal regions 612(1)-612(3) separated by a non-metal material 614 to reduce heat-related stress in the IC 600. The IC 600 may be the IC 500 in FIG. 5. Thus, the transistors 608 may be the transistors 508(1)-508(Z) in FIG. 5.

The layers 602(1)-602(5) include a bottom layer 602(1) disposed on terminals 616(1) and 616(2) of the transistors 608, which represent adjacent transistors in a row 606 of transistors 608 providing current in parallel, such as in a power amplifier, such as the row 102 of transistors 104(1)-104(X) in FIG. 1. The terminals 616(1) and 616(2) may be transistor contacts formed on a substrate, which may be a semiconductor substrate (e.g., GaAs or silicon). In some examples, the transistors 608 are heterojunction bipolar transistors (HBTs).

The layers 602(1)-602(5) also include a top layer 602(5) and intermediate layers 602(2)-602(4), which are disposed between, in the third, Z-axis direction, the bottom layer 602(1) and the top layer 602(5). Although there are five (5) layers 602(1)-602(T) shown herein, there may be any appropriate positive integer number T of layers in the pillar bar 604. In this example, the intermediate layers 602(2)-602(4) include a first, lower intermediate layer 602(2) in direct contact with the bottom layer 602(1), a third, upper intermediate layer 602(4) in direct contact with the top metal layer 602(5), and a second, middle intermediate layer 602(3) in direct contact with the first intermediate layer 602(2) and the third intermediate layer 602(4). Although referred to herein as the “top” metal layer, the pillar bar 604 may include another metal layer above the top metal layer 602(5).

In this example, the third intermediate layer 602(4) includes the separate metal regions 612(1)-612(3) separated in the first, X-axis direction by the non-metal material 614 to reduce stresses in the first direction caused by heating of the layers 602(1)-602(5) of the pillar bar 604. The terminals 616(1) and 616(2) in the row 606 of transistors 608 may conduct large currents, which causes resistive heating of the terminals 616(1) and 616(2). The non-metal material 614 may have a lower coefficient of thermal expansion than the separate metal regions 612(1)-612(3) and may be less rigid and/or elastic. Thus, the non-metal material 614 may be disposed in the intermediate layer 602(4) directly over, in the third direction orthogonal to a substrate 618 of the IC 600. In response to high currents causing increases in temperature, the separate metal regions 612(1)-612(3) may expand in the first direction, but the non-metal material 614 expands to a lesser degree (if at all) than the separate metal regions 612(1)-612(3) and may deform to absorb some of the expansion of the separate metal regions 612(1)-612(3) and thereby reduce stress in the IC 600.

The separate metal regions 612(1)-612(3) may be among the first metal regions 524A or the second metal regions 524B in FIG. 5, and the non-metal material 614 in FIG. 6 may be the non-metal material 516. In this example, each layer of the intermediate layers 602(2)-602(4), other than the first intermediate layer 602(4), comprises a continuous metal layer in the bar area 605. That is, each of the intermediate layers 602(2) and 602(3) in this example comprise a continuous metal layer that, if employed in the pillar bar 502 in FIG. 5, would extend from the first end 514A and the second end 514B in the first direction. In this example, each of the separate metal regions 612(1)-612(3) is coupled to the top layer 602(5) and to the intermediate layer 602(3) to provide a conductive path for heat and electricity in the third, Z-axis direction.

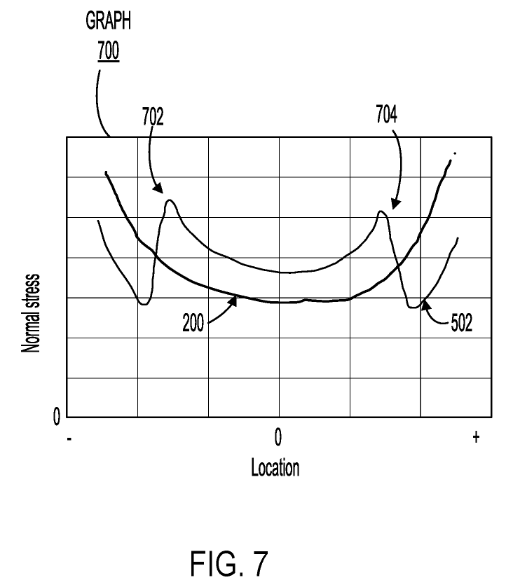

FIG. 7 is a graphical representation 700 of heat-related stresses created in the pillar bar 200 in FIG. 2 and heat-related stresses created in the pillar bar 502 in FIG. 5 provided for purposes of comparison. FIGS. 2 and 5 are also referenced. The horizontal axis of the graph 700 indicates locations along the row of transistors in the first, X-axis direction, where a middle point (0) of the X-axis corresponds to a middle of the pillar bar in the first direction. The vertical, Y-axis of the graph 700 indicates a magnitude of stress. As shown in FIG. 7, although the pillar bar 502 has higher stresses at ends 514A and 514B of the central metal region 522 corresponding to points 702 and 704 of the graph 700, the stress levels of the pillar bar 502 drop significantly between the central metal region 522 and the first metal regions 524A and the second metal regions 524B. The pillar bar 502 experiences much lower maximum stress levels than the pillar bar 200.

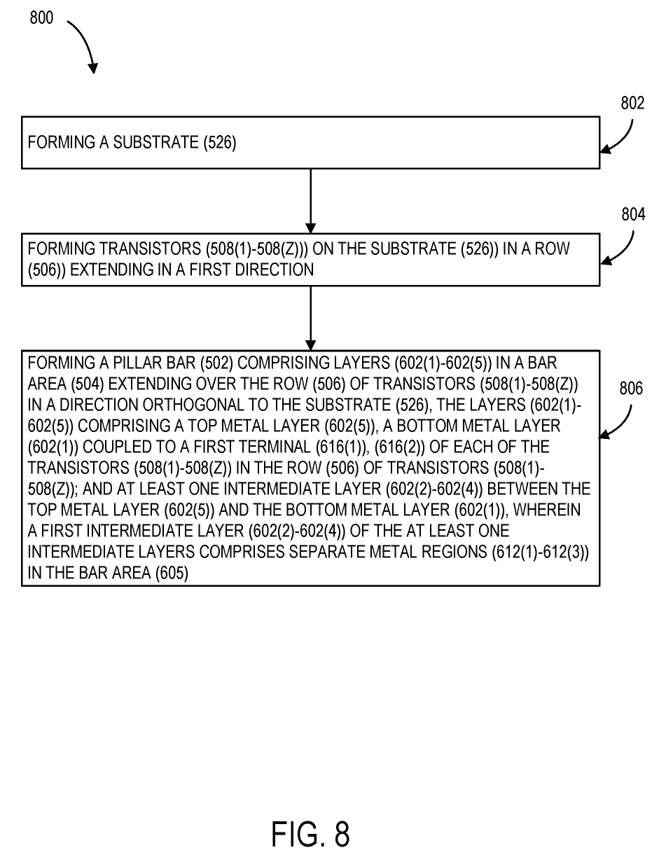

FIG. 8 is a flowchart of an exemplary method 800 of a process for manufacturing an IC such as the IC 500 in FIG. 5, in which an intermediate layer 510 includes separate metal regions 512(1)-512(S). The method 800 includes forming a substrate 526 (block 802) and forming transistors 508(1)-508(Z) on the substrate 526 in a row 506 extending in a first direction (block 804). The method also includes forming a pillar bar 502 comprising layers 602(1)-602(5) in a bar area 504 extending over the row 506 of transistors 508(1)-508(Z) in a direction orthogonal to the substrate 526, the layers 602(1)-602(5) comprising a top metal layer 602(5), a bottom metal layer 602(1) coupled to a terminal 616(1), 616(2) of each of the transistors 508(1)-508(Z) in the row 506 of transistors 508(1)-508(Z); and at least one intermediate layer 602(2)-602(4) between the top metal layer 602(5) and the bottom metal layer 602(1), wherein a first intermediate layer 602(2)-602(4) of the at least one intermediate layer 602(2)-602(4) comprises separate metal regions 612(1)-612(3) in the bar area 605 (block 806).

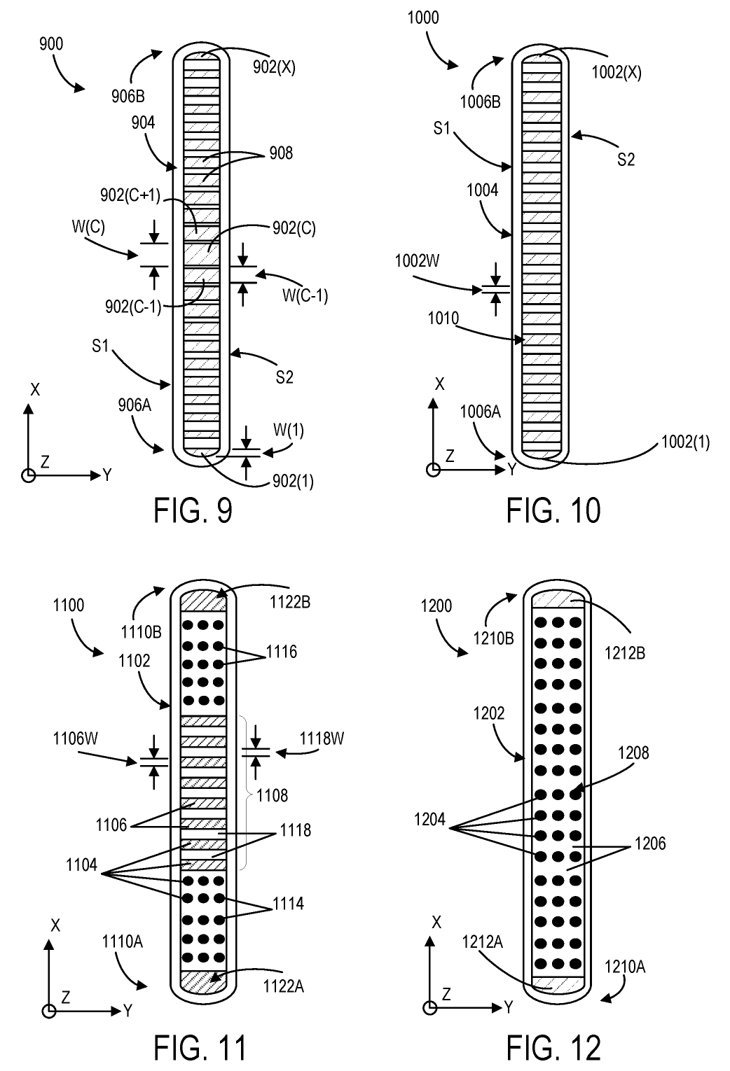

FIGS. 9-12 are additional examples of a first metal layer in at least one intermediate layer of a pillar bar, including separate metal regions to reduce heat-related stresses at each end of a bar area in an IC. The examples in FIGS. 9-12 may be employed to replace the intermediate layer 510 in FIG. 5 or the intermediate layer 602(4) in FIG. 6, which may be the same layer.

FIG. 9 is an illustration of intermediate layer 900, including separate metal regions 902(1)-902(X) in a bar area 904 having a first end 906A and a second end 906B in a first, X-axis direction. The separate metal regions 902(1)-902(X) may comprise metal strips 908 extending across the bar area 904 in a second, Y-axis direction between a first side S1 and a second side S2. A central metal region 902(C) of the separate metal regions 902(1)-902(X) disposed midway between the first end 906A and the second end 906B of the bar area 904 has a first width W(C) in the first direction. The widths W(C-1)-W(1) in the first direction of the plurality of separate metal regions 902(C-1)-902(1) between the central metal region 902(C) and the first end 906A progressively decrease from the central metal region 902(C) toward the first end 906A. Similarly, the widths of the separate metal regions 902(C+1)-902(X) between the central metal region 902(C) and the second end 906B also progressively decrease from the central metal region 902(C) toward the second end 906B.

FIG. 10 is an illustration of intermediate layer 1000, including separate metal regions 1002(1)-1002(X) in a bar area 1004 having a first end 1006A and a second end 1006B in a first, X-axis direction. Intermediate layer 1000 may be employed as the intermediate layer 510 in the pillar bar 502, as shown in FIG. 5. Each metal region of the plurality of separate metal regions 1002(1)-1002(X) extends across the bar area 1004 in the second, Y-axis direction from a first side S1 to a second side S2 of the bar area 1004, and each metal region of the separate metal regions 1002(1)-1002(X) has a same width 1002W in the first direction. In other words, the plurality of separate metal regions 1002(1)-1002(X) comprises metal strips extending parallel to each other in the second direction, and each has the same width 1002W in the first direction. Additionally, the plurality of separate metal regions 1002(1)-1002(X) are spaced apart a same distance by a non-metal material 1010. A width 1010W of non-metal material 1010 disposed between adjacent metal regions of the plurality of separate metal regions 1002(1)-1002(X) is consistent in the bar area 1004. At the first end 1006A and the second end 1006B, the plurality of separate metal regions 1002(1)-1002(X) in FIG. 10 appears to be semicircular in shape but may have a same shape (e.g., rectangular) as the other separate metal regions 1002(1)-1002(X).

FIG. 11 is an illustration of another example of an intermediate layer 1100 that may be employed in a bar area 1102 in a manner similar to the intermediate layer 510 in the pillar bar 502 in FIG. 5. The intermediate layer 1100 includes a central area 1108 midway between a first end 1110A and a second end 1110B in a first direction of the bar area 1102. Separate metal regions 1104 in the intermediate layer 1100 include a plurality of first metal regions 1114 disposed between the central area 1108 and the first end 1110A of the bar area 1102 and a plurality of second metal regions 1116 disposed between the central area 1108 and the second end 1110B. In the central area 1108, the separate metal regions 1104 include a plurality of third metal regions 1106. The third metal regions 1106 may each have a same width 1106W in the first direction and may be spaced apart a same distance 1118W in the first direction by a non-metal material 1118. Alternatively, the widths of the separate metal regions 1104 may be greatest at the midway point and decrease towards the first and second ends 1110A, 1110B, which is similar to the separate metal regions 902(1)-902(X) in FIG. 9. In contrast to the third metal regions 1106, the first metal regions 1114 and the second metal regions 1116 in this example are round or circular (but may be of any appropriate shape) and are disposed in a pattern, such as a two-dimensional array. The first metal regions 1114 and the second metal regions 1116 may be distributed randomly in the bar area 1102. At the first end 1110A and at the second end 1110B, the plurality of separate metal regions 1104 may be of any shapes, such as the semicircular metal regions 1122A and 1122B in FIG. 11.

FIG. 12 is an illustration of another example of an intermediate layer 1200 that may be employed in a bar area 1202, in a manner similar to the intermediate layer 510, in the pillar bar 502 in FIG. 5. The intermediate layer 1200 includes a plurality of separate metal regions 1204, which are round metal regions separated by a non-metal material 1206. The separate metal regions 1204 are disposed in a pattern 1208, and may be disposed in any appropriate alternative pattern, extending between a first end 1210A and a second end 1210B of the bar area 1202 in a first, X-axis direction. In a non-limiting example, the pattern 1208 in FIG. 12 is a two-dimensional array. In this example, the plurality of separate metal regions 1204 includes semicircular metal regions 1212A and 1212B at the first end 1210A and at the second end 1210B. These semicircular metal regions 1212A and 1212B may be omitted or replaced with separate metal regions of another appropriate shape.

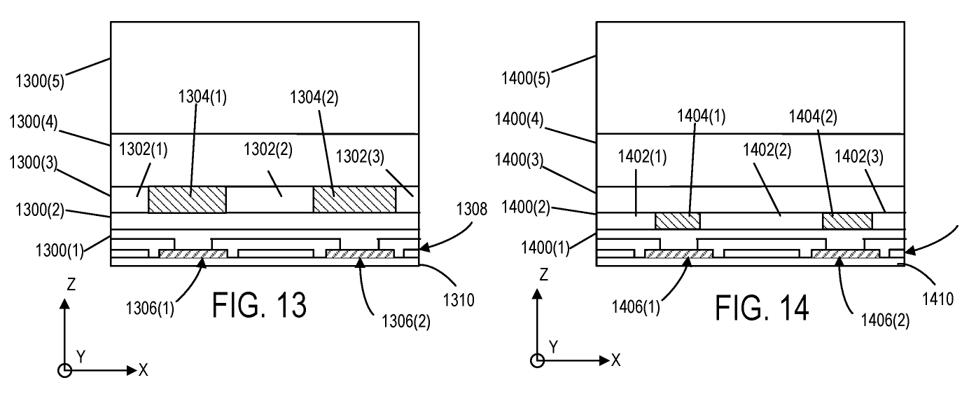

FIG. 13 is a cross-sectional side view of layers 1300(1)-1300(5) corresponding to the layers 602(1)-602(5) in FIG. 6 that may be employed in a pillar bar such as the pillar bar 502 in FIG. 5. The intermediate layers 1300(2)-1300(4) are disposed between the top layer 1300(5) and the bottom layer 1300(1). As an alternative to FIG. 6, in which the first, upper intermediate layer 602(4) includes a plurality of separate metal regions, in this example, the first intermediate layer 1300(4) is a continuous metal layer, and the second intermediate layer 1300(3) includes a plurality of separate metal regions 1302(1)-1302(3). The plurality of separate metal regions 1302(1)-1302(3) may represent a subset of a larger or smaller number of separate metal regions that may be disposed in the intermediate layer 1300(3). As shown, the second intermediate layer 1300(3) includes non-metal material 1304(1) and 1304(2) disposed directly over, in a third, Z-axis direction, terminals 1306(1), 1306(2) of transistors 1308 formed in a row (not shown) on a substrate 1310.

FIG. 14 is a cross-sectional side view of layers 1400(1)-1400(5) corresponding to the layers 602(1)-602(5) in FIG. 6 that may be employed in a pillar bar such as the pillar bar 502 in FIG. 5. In this example, the third intermediate layer 1400(2), which is in direct contact with the bottom metal layer 1400(1), includes separate metal regions 1402(1)-1402(3), which may be included in a larger plurality of separate metal regions. The intermediate layer 1402(2) includes non-metal material 1404(1), 1404(2) disposed directly over, in the third, Z-axis direction, terminals 1406(1) and 1406(2) of transistors 1408 formed on a substrate 1410.

ICs, including pillar bars disposed on a row of transistors and having intermediate layers with a plurality of separate metal regions to reduce stresses, may be included in processor-based devices. Examples of such processor-based devices, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

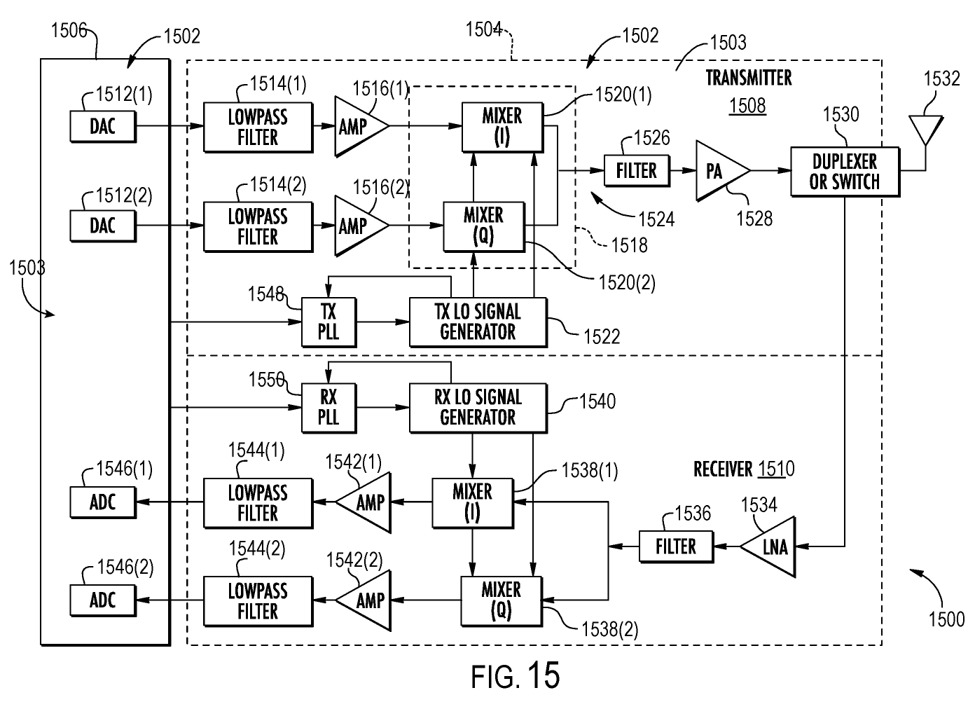

FIG. 15 illustrates an exemplary wireless communications device 1500 that includes radio-frequency (RF) components formed from one or more ICs 1502, wherein any of the ICs 1502 may include pillar bars disposed on a row of transistors and having intermediate layers with a plurality of separate metal regions to reduce stresses, as shown in FIGS. 5, 6, andFIGS. 9-13 may be included in processor-based devices. The wireless communications device 1500 may include or be provided in any of the above-referenced devices as examples. As shown in FIG. 15, the wireless communications device 1500 includes a transceiver 1504 and a data processor 1506. The data processor 1506 may include a memory to store data and program codes. The transceiver 1504 includes a transmitter 1508 and a receiver 1510 that support bi-directional communications. In general, the wireless communications device 1500 may include any number of transmitters 1508 and/or receivers 1510 for any number of communication systems and frequency bands. All or a portion of the transceiver 1504 may be implemented on one or more analog ICs, RF ICs (RFICs), mixed-signal ICs, etc.

The transmitter 1508 or the receiver 1510 may be implemented with a super-heterodyne or direct-conversion architecture. In the super-heterodyne architecture, a signal is frequency-converted between RF and baseband in multiple stages, for example, from RF to an intermediate frequency (IF) in one stage and then from IF to baseband in another stage for the receiver 1510. In the direct-conversion architecture, a signal is frequency-converted between RF and baseband in one stage. The super-heterodyne and direct-conversion architectures may use different circuit blocks and/or have different requirements. In the wireless communications device 1500 in FIG. 15, the transmitter 1508 and the receiver 1510 are implemented with the direct-conversion architecture.

In the transmit path, the data processor 1506 processes data to be transmitted and provides I and Q analog output signals to the transmitter 1508. In the exemplary wireless communications device 1500, the data processor 1506 includes digital-to-analog converters (DACs) 1512(1), 1512(2) for converting digital signals generated by the data processor 1506 into the I and Q analog output signals (e.g., I and Q output currents) for further processing.

Within the transmitter 1508, lowpass filters 1514(1), 1514(2) filter the I and Q analog output signals, respectively, to remove undesired signals caused by the prior digital-to-analog conversion. Amplifiers (AMPs) 1516(1), 1516(2) amplify the signals from the lowpass filters 1514(1), 1514(2), respectively, and provide I and Q baseband signals. An upconverter 1518 upconverts the I and Q baseband signals with I and Q transmit (TX) local oscillator (LO) signals through mixers 1520(1), 1520(2) from a TX LO signal generator 1522 to provide an upconverted signal 1524. A filter 1526 filters the upconverted signal 1524 to remove undesired signals caused by the frequency up-conversion as well as noise in a receive frequency band. A power amplifier (PA) 1528 amplifies the upconverted signal 1524 from the filter 1526 to obtain the desired output power level and provides a transmit RF signal. The transmit RF signal is routed through a duplexer or switch 1530 and transmitted via an antenna 1532.

In the receive path, the antenna 1532 receives signals transmitted by base stations and provides a received RF signal, which is routed through the duplexer or switch 1530 and provided to a low noise amplifier (LNA) 1534. The duplexer or switch 1530 is designed to operate with a specific receive (RX)-to-TX duplexer frequency separation, such that RX signals are isolated from TX signals. The received RF signal is amplified by the LNA 1534 and filtered by a filter 1536 to obtain a desired RF input signal. Down-conversion mixers 1538(1), 1538(2) mix the output of the filter 1536 with I and Q RX LO signals (i.e., LO_I and LO_Q) from an RX LO signal generator 1540 to generate I and Q baseband signals. The I and Q baseband signals are amplified by AMPs 1542(1), 1542(2) and further filtered by lowpass filters 1544(1), 1544(2) to obtain I and Q analog input signals, which are provided to the data processor 1506. In this example, the data processor 1506 includes analog-to-digital converters (ADCs) 1546(1), 1546(2) for converting the analog input signals into digital signals to be further processed by the data processor 1506.

In the wireless communications device 1500 of FIG. 15, the TX LO signal generator 1522 generates the I and Q TX LO signals used for frequency up-conversion, while the RX LO signal generator 1540 generates the I and Q RX LO signals used for frequency down-conversion. Each LO signal is a periodic signal with a particular fundamental frequency. A TX phase-locked loop (PLL) circuit 1548 receives timing information from the data processor 1506 and generates a control signal used to adjust the frequency and/or phase of the TX LO signals from the TX LO signal generator 1522. Similarly, an RX PLL circuit 1550 receives timing information from the data processor 1506 and generates a control signal used to adjust the frequency and/or phase of the RX LO signals from the RX LO signal generator 1540.

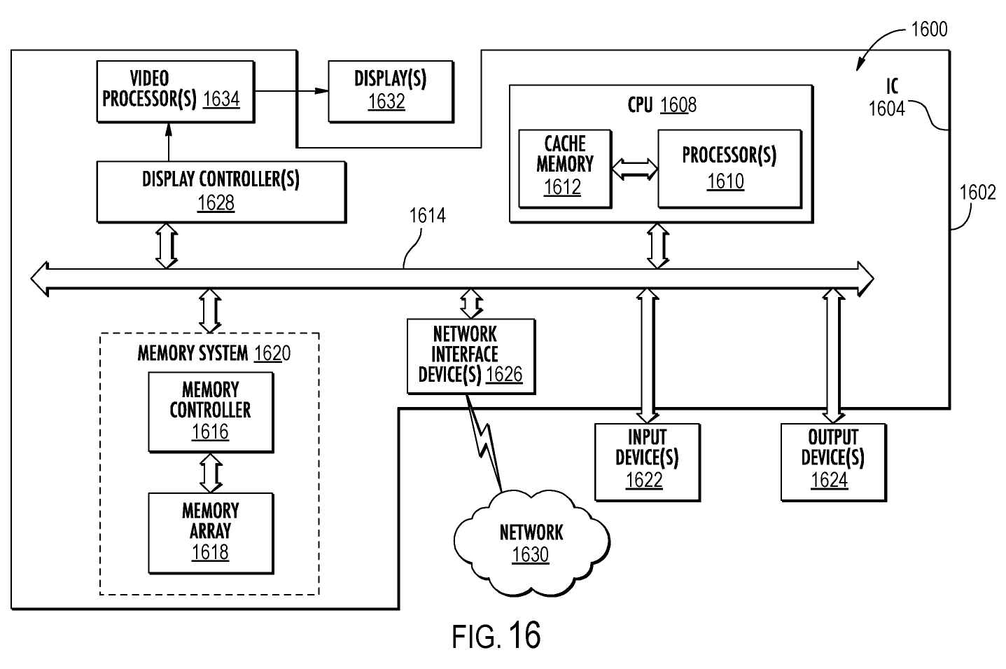

In this regard, FIG. 16 illustrates an example of a processor-based system 1600 that can include pillar bars disposed on a row of transistors and having intermediate layers with a plurality of separate metal regions to reduce stresses, as shown in FIGS. 5, 6, andFIGS. 9-13 . The processor-based system 1600 includes a central processing unit (CPU) 1608 that includes one or more processors 1610, which may also be referred to as CPU cores or processor cores. The CPU 1608 may have cache memory 1612 coupled to the CPU 1608 for rapid access to temporarily stored data. The CPU 1608 is coupled to a system bus 1614 and can intercouple master and slave devices included in the processor-based system 1600. As is well known, the CPU 1608 communicates with these other devices by exchanging address, control, and data information over the system bus 1614. For example, the CPU 1608 can communicate bus transaction requests to a memory controller 1616, as an example of a slave device. Although not illustrated in FIG. 16, multiple system buses 1614 could be provided, wherein each system bus 1614 constitutes a different fabric.

Other master and slave devices can be connected to the system bus 1614. As illustrated in FIG. 16, these devices can include a memory system 1620 that includes the memory controller 1616 and a memory array(s) 1618, one or more input devices 1622, one or more output devices 1624, one or more network interface devices 1626, and one or more display controllers 1628, as examples. The input device(s) 1622 can include any type of input device, including, but not limited to, input keys, switches, voice processors, etc. The output device(s) 1624 can include any type of output device, including, but not limited to, audio, video, other visual indicators, etc. The network interface device(s) 1626 can be any device configured to allow an exchange of data to and from a network 1630. The network 1630 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1626 can be configured to support any type of communications protocol desired.

The CPU 1608 may also be configured to access the display controller(s) 1628 over the system bus 1614 to control information sent to one or more displays 1632. The display controller(s) 1628 sends information to the display(s) 1632 to be displayed via one or more video processor(s) 1634, which processes the information to be displayed into a format suitable for the display(s) 1632. The display(s) 1632 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:

1. An integrated circuit (IC) comprising:

a substrate;

a row of transistors on the substrate, the row of transistors extending in a first direction; and

a pillar bar comprising layers in a bar area extending on the row of transistors, the layers comprising:

a top metal layer;

a bottom metal layer coupled to a terminal of each transistor in the row of transistors; and

at least one intermediate layer between the top metal layer and the bottom metal layer,

wherein a first intermediate layer of the at least one intermediate layer comprises separate metal regions in the bar area.

2. The IC of clause 1, wherein each layer of the at least one intermediate layer, other than the first intermediate layer, comprises a continuous metal layer in the bar area.

3. The IC of clause 1 or clause 2, wherein the first intermediate layer of the at least one intermediate layer further comprises a non-metal material between each of the separate metal regions.

4. The IC of clause 3, wherein the non-metal material comprises a polymer.

5. The IC of clause 3 or clause 4, wherein the non-metal material in the first intermediate layer is disposed directly over, in a third direction orthogonal to the substrate, the terminal of each transistor in the row of transistors.

6. The IC of any of clause 1 to clause 5, wherein:

the bar area comprises a central area midway between a first end and a second end of the bar area in the first direction; and

the separate metal regions comprise:

a central metal region in the central area;

a plurality of first metal regions between the central area and the first end of the bar area; and

a plurality of second metal regions between the central area and the second end of the bar area.

7. The IC of clause 6, wherein:

each of the plurality of first metal regions and each of the plurality of second metal regions extend across the bar area in a second direction orthogonal to the first direction from a first side of the bar area to a second side of the bar area; and

the non-metal material extends in the second direction across the bar area from the first side to the second side between adjacent first metal regions of the plurality of first metal regions and between adjacent second metal regions of the plurality of second metal regions.

8. The IC of clause 7 or clause 8, wherein:

the central metal region comprises a metal layer having a width in the first direction equal to or greater than half a distance from the first end to the second end of the bar area.

9. The IC of clause 7, wherein:

the central metal region comprises a plurality of third metal regions each having a length extending across the bar area in the second direction from a first side to a second side of the bar area and separated from each other by a non-metal material.

10. The IC of any of clause 1 to clause 5, wherein:

the separate metal regions in the bar area comprise metal strips extending across the bar area in a second direction; and

a central metal region of the separate metal regions is disposed midway between a first end and a second end of the bar area in the first direction and has a first width in the first direction;

widths in the first direction of the separate metal regions between the central metal region and the first end progressively decrease from the central metal region toward the first end; and

widths in the first direction of the separate metal regions between the central metal region and the second end progressively decrease from the central metal region toward the second end.

11. The IC of any of clause 1 to clause 5, wherein:

each of the separate metal regions has a same width in a first direction between a first end and a second end of the bar area; and

each of the separate metal regions extends across the bar area in a second direction orthogonal to the first direction from a first side to a second side of the bar area.

12. The IC of any of clause 1 to clause 11, wherein the separate metal regions comprise a semicircular metal region at each of a first end and a second end of the bar area.

13. The IC of any of clause 1 to clause 12, wherein the at least one intermediate layer comprises:

a lower intermediate layer in direct contact with the bottom metal layer;

an upper intermediate layer in direct contact with the top metal layer; and

a middle intermediate layer in direct contact with the lower intermediate layer and the upper intermediate layer.

14. The IC of clause 13, wherein the first intermediate layer of the at least one intermediate layer comprises the upper intermediate layer.

15. The IC of clause 13, wherein the first intermediate layer of the at least one intermediate layer comprises the middle intermediate layer.

16. The IC of clause 13, wherein the first intermediate layer of the at least one intermediate layer comprises the lower intermediate layer.

17. The IC of any of clause 1 to clause 16, wherein each transistor in the row of transistors comprises a heterojunction bipolar transistor.

18. The IC of any of clause 1 to clause 17, wherein:

the bar area comprises an oblong area; and

the row of transistors is between the pillar bar and the substrate.

19. The IC of clause 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

20. A method of fabricating an integrated circuit (IC), comprising:

forming a substrate;

forming transistors on the substrate in a row extending in a first direction; and

forming a pillar bar comprising layers in a bar area extending over the row of transistors in a direction orthogonal to the substrate, the layers comprising:

a top metal layer;

a bottom metal layer coupled to a terminal of each transistor in the row of transistors; and

at least one intermediate layer between the top metal layer and the bottom metal layer,

wherein a first intermediate layer of the at least one intermediate layer comprises separate metal regions in the bar area.

21. An integrated circuit (IC) package comprising:

a first IC comprising logic circuits; and

a second IC comprising a power amplifier disposed on a substrate and configured to supply power to the first IC, the power amplifier comprising:

a row of transistors disposed on the substrate and extending in a first direction; and

a pillar bar comprising a stack of layers in a bar area extending over the row of transistors in a direction orthogonal to the substrate, the stack of layers comprising:

a top metal layer;

a bottom metal layer coupled to a terminal of each transistor in the row of transistors; and

at least one intermediate layer between the top metal layer and the bottom metal layer,

wherein a first intermediate layer of the at least one intermediate layer comprises separate metal regions in the bar area, which comprises a central area midway between a first end and a second end in the first direction.

What is claimed is:

1. An integrated circuit (IC) comprising:
a substrate;
a row of transistors on the substrate, the row of transistors extending in a first direction; and
a pillar bar comprising layers in a bar area extending on the row of transistors, the layers comprising:
a top metal layer;
a bottom metal layer coupled to a terminal of each transistor in the row of transistors; and
at least one intermediate layer between the top metal layer and the bottom metal layer,
wherein a first intermediate layer of the at least one intermediate layer comprises separate metal regions in the bar area.

2. The IC of claim 1, wherein each layer of the at least one intermediate layer, other than the first intermediate layer, comprises a continuous metal layer in the bar area.

3. The IC of claim 1, wherein the first intermediate layer of the at least one intermediate layer further comprises a non-metal material between each of the separate metal regions.

4. The IC of claim 3, wherein the non-metal material comprises a polymer.

5. The IC of claim 3, wherein the non-metal material in the first intermediate layer is disposed directly over, in a third direction orthogonal to the substrate, the terminal of each transistor in the row of transistors.

6. The IC of claim 1, wherein:
the bar area comprises a central area midway between a first end and a second end of the bar area in the first direction; and
the separate metal regions comprise:
a central metal region in the central area;
a plurality of first metal regions between the central area and the first end of the bar area; and
a plurality of second metal regions between the central area and the second end of the bar area.

7. The IC of claim 6, wherein:
each of the plurality of first metal regions and each of the plurality of second metal regions extend across the bar area in a second direction orthogonal to the first direction from a first side of the bar area to a second side of the bar area; and
the non-metal material extends in the second direction across the bar area from the first side to the second side between adjacent first metal regions of the plurality of first metal regions and between adjacent second metal regions of the plurality of second metal regions.

8. The IC of claim 7, wherein:
the central metal region comprises a metal layer having a width in the first direction equal to or greater than half a distance from the first end to the second end of the bar area.

9. The IC of claim 7, wherein:
the central metal region comprises a plurality of third metal regions each having a length extending across the bar area in the second direction from a first side to a second side of the bar area and separated from each other by a non-metal material.

10. The IC of claim 1, wherein:
the separate metal regions in the bar area comprise metal strips extending across the bar area in a second direction; and
a central metal region of the separate metal regions is disposed midway between a first end and a second end of the bar area in the first direction and has a first width in the first direction;
widths in the first direction of the separate metal regions between the central metal region and the first end progressively decrease from the central metal region toward the first end; and
widths in the first direction of the separate metal regions between the central metal region and the second end progressively decrease from the central metal region toward the second end.

11. The IC of claim 1, wherein:
each of the separate metal regions has a same width in a first direction between a first end and a second end of the bar area; and
each of the separate metal regions extends across the bar area in a second direction orthogonal to the first direction from a first side to a second side of the bar area.

12. The IC of claim 1, wherein the separate metal regions comprise a semicircular metal region at each of a first end and a second end of the bar area.

13. The IC of claim 1, wherein the at least one intermediate layer comprises:
a lower intermediate layer in direct contact with the bottom metal layer;
an upper intermediate layer in direct contact with the top metal layer; and
a middle intermediate layer in direct contact with the lower intermediate layer and the upper intermediate layer.

14. The IC of claim 13, wherein the first intermediate layer of the at least one intermediate layer comprises the upper intermediate layer.

15. The IC of claim 13, wherein the first intermediate layer of the at least one intermediate layer comprises the middle intermediate layer.

16. The IC of claim 13, wherein the first intermediate layer of the at least one intermediate layer comprises the lower intermediate layer.

17. The IC of claim 1, wherein each transistor in the row of transistors comprises a heterojunction bipolar transistor.

18. The IC of claim 1, wherein:
the bar area comprises an oblong area; and
the row of transistors is between the pillar bar and the substrate.

19. The IC of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

20. A method of fabricating an integrated circuit (IC), comprising:
forming a substrate;
forming transistors on the substrate in a row extending in a first direction; and
forming a pillar bar comprising layers in a bar area extending over the row of transistors in a direction orthogonal to the substrate, the layers comprising:
a top metal layer;
a bottom metal layer coupled to a terminal of each transistor in the row of transistors; and
at least one intermediate layer between the top metal layer and the bottom metal layer,
wherein a first intermediate layer of the at least one intermediate layer comprises separate metal regions in the bar area.

21. An integrated circuit (IC) package comprising:
a first IC comprising logic circuits; and
a second IC comprising a power amplifier disposed on a substrate and configured to supply power to the first IC, the power amplifier comprising:
a row of transistors disposed on the substrate and extending in a first direction; and
a pillar bar comprising a stack of layers in a bar area extending over the row of transistors in a direction orthogonal to the substrate, the stack of layers comprising:
a top metal layer;
a bottom metal layer coupled to a terminal of each transistor in the row of transistors; and
at least one intermediate layer between the top metal layer and the bottom metal layer,
wherein a first intermediate layer of the at least one intermediate layer comprises separate metal regions in the bar area, which comprises a central area midway between a first end and a second end in the first direction.
